(19) United States
(12) Patent Application Publication
(10) Pub. No.: US 2025/0244782 A1
(43) Pub. Date: Jul. 31, 2025

(54) Voltage detection circuit and voltage detection system

(71) Applicant: INFSITRONIX TECHNOLOGY CORPORATION, Hsinchu County (TW)

(72) Inventors: Hui-Tsung Yang, Hsinchu County (TW); WEI-CHUN LU, Hsinchu County (TW); SHIH-WEI SHEN, Hsinchu County (TW); CHUNG-JYE HSU, Hsinchu County (TW)

(21) Appl. No.: 19/036,193

(22) Filed: Jan. 24, 2025

Related U.S. Application Data
(60) Provisional application No. 63/625,303, filed on Jan. 26, 2024.

(51) Int. Cl. G05F 1/571; G06F 1/30; H02H 3/02; H03K 17/082

(52) U.S. Cl. CPC G05F 1/571; H02H 3/023; H03K 17/082; G06F 1/305

(57) ABSTRACT

The present application discloses a voltage detection circuit and a voltage detection system. The voltage detection circuit includes a control terminal, a load terminal and a voltage detection unit. The control terminal includes a control terminal voltage, the load terminal includes a load terminal voltage, and the voltage detection unit detects the control terminal voltage and the load terminal voltage at the control terminal and the load terminal. The voltage detection circuit converts the control terminal voltage to a low level voltage according to a voltage between the control terminal voltage and the load terminal voltage. The voltage detection system includes a switch circuit and a voltage detection circuit.

### FIELD OF THE INVENTION

The present application relates to a voltage detection circuit and voltage detection system, particularly to a voltage detection circuit and system with short-circuit protection.

### BACKGROUND OF THE INVENTION

In power systems, if a switch circuit is adopted at a load terminal, when a short-circuit state occurs at the load terminal, a maximum current limit will flow through the switch circuit. Therefore, in this situation, as the output power increases, the safe operation area (SOA) of the switch circuit needs to be enhanced. This requires setting corresponding protection times according to a capacitance of an output capacitor. In applications with larger capacitance output capacitors, the SOA of the switch circuit also needs to be increased. Before implementing over current protection (OCP), the system must need a technical solution able to instantly and automatically detect short-circuit conditions and automatically shut down the switch circuit to protect the power system and the switch circuit.

### SUMMARY

An objective of the present application is to provide a voltage detection circuit, including a control terminal, a load terminal, and a voltage detection unit. The control terminal includes a control terminal voltage, and the load terminal includes a load terminal voltage. The voltage detection unit, coupled between the control terminal and the load terminal, may instantly detect the voltage difference between the control and load terminal voltages and convert the control terminal voltage to a low level voltage, achieving an instant short-circuit protection.

An objective of the present application is to provide a voltage detection circuit, including a control terminal, a load terminal, and a voltage detection unit. The control terminal includes a control terminal voltage, and the load terminal includes a load terminal voltage. When the control terminal voltage exceeds the load terminal voltage by a threshold voltage, the voltage detection unit converts the control terminal voltage to a low level voltage, achieving the instant short-circuit protection.

An objective of the present application is to provide a voltage detection circuit, including a control terminal, a load terminal, and a voltage detection unit. The control terminal includes a control terminal voltage, and the load terminal includes a load terminal voltage. When the control terminal voltage exceeds the load terminal voltage by a multiple of the threshold voltage, the voltage detection unit converts the control terminal voltage to a low level voltage, preventing from a false detection of fault conditions and effectively achieving short-circuit protection.

An objective of the present application is to provide a voltage detection system, including a switch circuit and a voltage detection circuit. The switch circuit includes a first terminal, a second terminal, and a control terminal. The voltage detection circuit may instantly detect the voltage between the second terminal and the control terminal of the switch circuit and disconnect the switch circuit, achieving the instant short-circuit protection.

The present application provides a voltage detection circuit, including a control terminal, a load terminal, and a voltage detection unit. The control terminal includes a control terminal voltage, and the load terminal includes a load terminal voltage. According to the voltage between the control terminal voltage and the load terminal voltage, the control terminal voltage is converted to a low level voltage.

The present application provides a voltage detection system, including a switch circuit and a voltage detection circuit. The switch circuit includes a first terminal, a second terminal, and a control terminal. The first terminal is coupled to a power source, the second terminal is coupled to a load, and the voltage detection circuit is coupled to the switch circuit. The voltage detection circuit disconnects the switch circuit according to the voltage between the second terminal and the control terminal.

### BRIEF DESCRIPTION OF THE DRAWINGS

FIG. 1: which is a schematic diagram of the voltage detection system according to an embodiment of the present application;

FIG. 2: which is a schematic diagram of the voltage detection circuit according to an embodiment of the present application;

FIG. 3: which is a circuit diagram of the voltage detection circuit according to an embodiment of the present application;

FIG. 4: which is a circuit diagram of the voltage detection circuit according to another embodiment of the present application.

### DETAILED DESCRIPTION

To provide the esteemed examiners with a further understanding and recognition of the features and effects achieved by the present application, detailed explanations are provided in conjunction with embodiments as follows:

Certain terms used in the specification and claims refer to specific components; however, those skilled in the art should understand that manufacturers may use different terms to refer to the same component, and furthermore, the specification and claims do not distinguish components based on the difference in names, but rather on the differences in the components in terms of overall technology. Throughout the specification and claims, the term “comprising” is an open-ended term and should be interpreted as “including but not limited to.” Moreover, the term “coupled” herein includes any means of direct and indirect connection. Therefore, if the text describes a first device coupled to a second device, it means that the first device may be directly connected to the second device, or may be indirectly connected to the second device through other devices or means of connection.

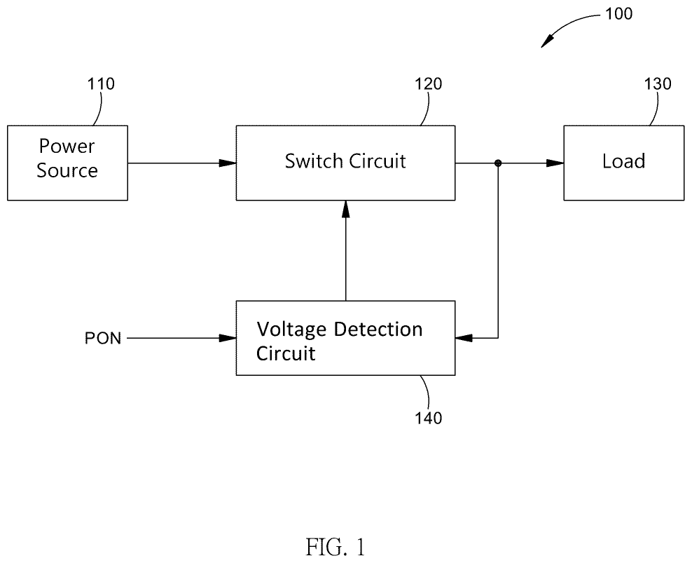

Please refer to FIG. 1, which is a schematic diagram of a voltage detection system according to an embodiment of the present application. The voltage detection system 100 according to the present application is applied for short-circuit protection, and the voltage detection system 100 includes a power source 110, a switch circuit 120, a load 130, and a voltage detection circuit 140. The power source 110 is coupled to the load 130 through the switch circuit 120, and the voltage detection circuit 140 is coupled to the switch circuit 120, and activated by a power drive signal PON. In an embodiment, the voltage detection system 100 is used in a power system of a personal computer, wherein the power source 110 is a main power supply of a computer host, the load 130 is a graphics card inside the computer host, and both the switch circuit 120 and the voltage detection circuit 140 are disposed inside the computer host and applied for a power supply to supply power to the graphics card.

In this embodiment, the switch circuit 120 includes a first terminal, a second terminal, and a control terminal. The first terminal of the switch circuit 120 is coupled to the power source 110, and the second terminal of the switch circuit 120 is coupled to the load 130. The voltage detection circuit 140 is coupled to the switch circuit 120 and disconnects the switch circuit 120 according to the voltage between the second terminal and the control terminal of the switch circuit 120. For example, when the voltage between the second terminal and the control terminal exceeds the threshold voltage set by the voltage detection circuit 140, indicative of a short circuit fault condition, the voltage detection circuit 140 activates the short circuit protection function and disconnects the switch circuit 120, preventing the power source 110 from connecting to load 130. In an embodiment, when the voltage between the second terminal and the control terminal of the switch circuit 120 exceeds a multiple of the threshold voltage set by the voltage detection circuit 140, the voltage detection circuit 140 disconnects the switch circuit 120, for example, from 1.1 to 1.5 times the threshold voltage, other multiples are possible. The present application is not limited thereto. That is, a tolerance range is set to avoid system misjudgment, when the voltage between the second terminal and the control terminal exceeds the threshold voltage. If this exceeding condition persists and the voltage difference between the second terminal and the control terminal increases, which are indicative of occurring a short circuit fault condition in fact, prompting the voltage detection circuit 140 to disconnect the switch circuit 120 for performing the short circuit protection function.

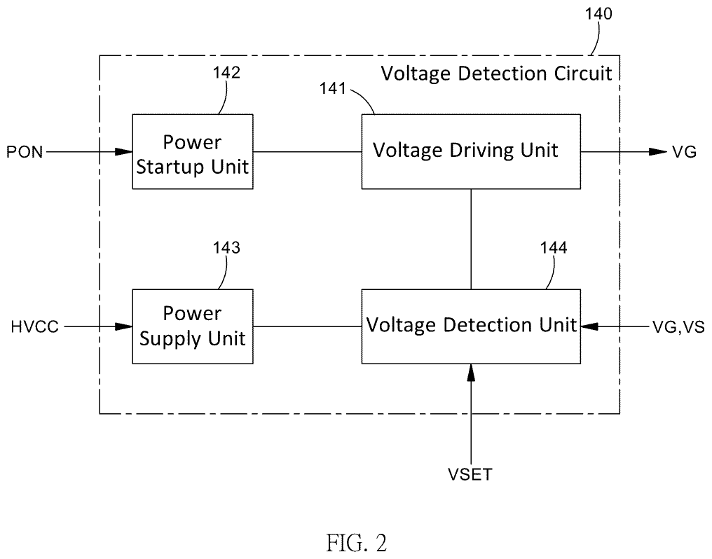

Please refer to FIG. 2, which is a schematic diagram of a voltage detection circuit according to an embodiment of the present application. The voltage detection circuit 140 includes a voltage driving unit 141, a power startup unit 142, a power supply unit 143, and a voltage detection unit 144. The power supply unit 143 receives a power voltage HVCC to supply the necessary power for the voltage detection circuit 140, when the power supply unit 143 receives the power voltage HVCC, it indicates that the system is starting up or booting, for example, when a user presses the power button on the personal computer to start up the personal computer. Upon system startup, the power startup unit 142 receives the power drive signal PON, which is, for example, a low-level signal, and the voltage detection circuit 140 activates to perform a short-circuit protection function. When the voltage detection circuit 140 is activated, the voltage driving unit 141 generates a control terminal voltage VG to change the control terminal voltage VG, and the voltage detection unit 144 receives the control terminal voltage VG, the load terminal voltage VS, and the threshold voltage VSET.

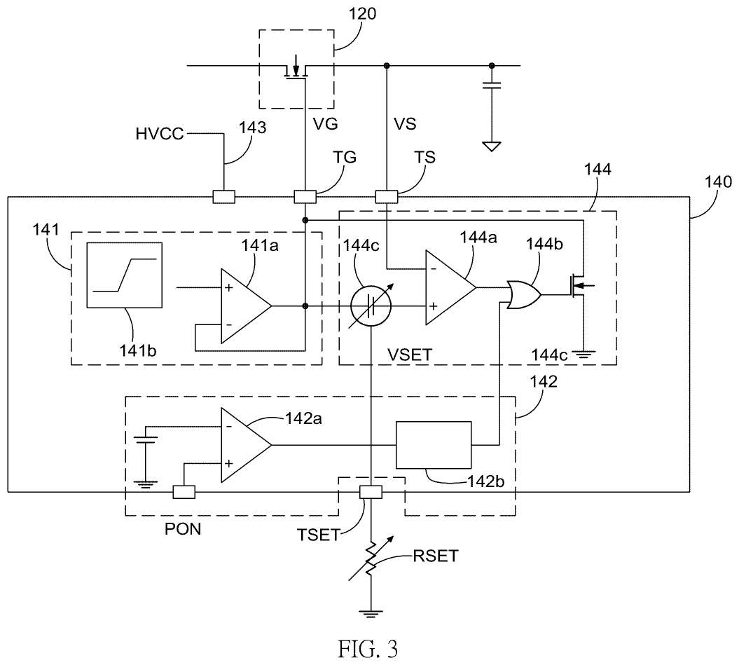

Please refer to FIG. 3, which is a circuit diagram of the voltage detection circuit according to an embodiment of the present application. The voltage detection circuit 140 includes a control terminal TG, a load terminal TS, a setting terminal TSET, a voltage driving unit 141, a power startup unit 142, a power supply unit 143, and a voltage detection unit 144. The voltage detection unit 144 is coupled to the control terminal TG and the load terminal TS, and changes the control terminal TG voltage to a low level voltage according to the voltage between the control terminal voltage VG and the load terminal voltage VS. There is a detection voltage between the control terminal voltage VG and the load terminal voltage VS. In this embodiment, the detection voltage is a voltage difference between the control terminal voltage VG and the load terminal voltage VS. The voltage detection unit 144 sets the threshold voltage VSET, and when the detection voltage exceeds the threshold voltage VSET, it is indicative of a short-circuit fault condition. The voltage detection unit 144 then performs the short-circuit protection function, changing the control terminal voltage VG to a low level voltage to disconnect the switch circuit 120, halting the conduction between the power source 110 and the load 130.

In an embodiment, the voltage detection unit 144 sets the threshold as a multiple of the threshold voltage VSET, that is, the voltage detection unit 144 performs the short-circuit protection function when the detected voltage exceeds the multiple of the threshold voltage VSET, such as 1.1 to 1.5 times the threshold voltage VSET, other multiples are also possible, and the present application is not limited to these values. Using the multiple of the threshold voltage VSET as the threshold may prevent the system from misjudging the fault conditions. When the voltage between the second terminal and the control terminal exceeds the threshold voltage and the difference continues to increase, it indicates a short-circuit fault condition while the voltage detection unit 144 then converts the control terminal voltage VG, causing the switch circuit 120 disconnected with the power source and the load and perform the short-circuit protection function.

In this embodiment, the threshold voltage VSET of the voltage detection unit 144 is set according to the setting terminal TSET, which is coupled to the voltage detection unit 144. The setting terminal TSET is coupled to a variable resistor, and adjusting the resistance of the variable resistor may adjust the threshold voltage VSET, which may be set to values such as 1 volt or 1.2 volts, but the present application is not limited to these values, and the threshold voltage VSET may be any value.

In this embodiment, the voltage detection unit 144 includes a comparator 144a, a logic circuit 144b, and a voltage source 144c. The comparator 144a is coupled to the control terminal TG and the load terminal TS, and comparator 144a compares the control terminal voltage VG with the load terminal voltage VS and outputs a comparison result. The logic circuit 144b is coupled to the comparator 144a, and according to the comparison result, the logic circuit 144b outputs a control signal. The voltage detection unit 144 changes the control terminal voltage VG to a low level voltage according to the control signal. In this embodiment, the voltage detection unit 144 further includes a switch component including a first terminal, a second terminal, and a third terminal. The first terminal is coupled to the control terminal TG, the second terminal is coupled to the ground, and the third terminal is coupled to the logic circuit 144b. In this embodiment, the switch component is a transistor switch. As shown in the figure, when the control terminal voltage VG exceeds the load terminal voltage VS beyond the threshold voltage VSET, the logic circuit 144b outputs the control signal to the switch component, causing the switch component to conduct. The control terminal TG is coupled to the ground level through the conducting switch component, causing the control terminal voltage VG to become or approach the ground level, which is, for example, 0 volts. As the control terminal voltage VG becomes the ground level, the switch circuit 120 is disconnected, achieving an immediate short-circuit protection effect. In this embodiment, the comparator 144a is, for example, an operational amplifier (OPA).

In this embodiment, the voltage drive unit 141 is coupled to the voltage detection circuit 144 and the control terminal TG. The voltage drive unit 141 generates the control terminal voltage VG and outputs it to the control terminal TG to change the control terminal voltage VG. The voltage drive unit 141 includes an operational amplifier 141a and a ramp generator 141b. Upon system startup or boot-up, the ramp generator 141b generates a ramp to the operational amplifier 141a according to a set slope, causing the operational amplifier 141a to generate a ramp voltage according to the received ramp and output the ramp voltage to the control terminal TG, thereby changing the control terminal voltage VG, which rises according to the ramp voltage, at this time, the voltage detection unit 144 detects whether the control terminal voltage VG and the load terminal voltage VS exceed the threshold voltage VSET.

In this embodiment, the power startup unit 142 is coupled to the voltage detection unit 144, and upon system boot or startup, the power startup unit 142 outputs a start signal to the voltage detection unit 144. The power startup unit 142 includes a comparator 142a and a debouncing component 142b. During system boot or startup, the power drive signal PON is at a low level and is input to one terminal of the comparator 142a, the comparator 142a receives a start voltage at the other terminal, comparing whether the power drive signal PON is less than the start voltage, if the power drive signal PON is less than the start voltage, then comparator 142a sends a start signal to the debouncing component 142b, which is used to suppress oscillations of the start signal, such as when a user presses and releases the power button, causing oscillations due to the mechanical switch operation of the power button, the debouncing component 142b suppresses the oscillations of the start signal and outputs start signal to the logic circuit 144b of the voltage detection unit 144, the start signal is, for example, a low-level signal, the present application is not limited to this. The logic circuit 144b determines whether to send a control signal to the switching components within the voltage detection unit 144 according to the start signal and the comparison results of comparator 144a. In this embodiment, comparator 142a is, for example, an operational amplifier.

In this embodiment, the power supply unit 143 is a power supply, the power supply unit 143 provides a voltage required by the voltage detection circuit 140. The power supply unit 143 receives a power voltage HVCC, such as a high voltage of 15 to 18 volts, and steps down the power voltage HVCC to the voltage required by the voltage detection circuit 140, such as 12 volts, the present application is not limited to this.

In this embodiment, the switching circuit 120 is exemplified by an N-type transistor, such as a Metal-Oxide-Semiconductor Field-Effect Transistor (MOSFET). The present application is not limited to this, and the switching circuit 120 may be any type of transistor or any component with switching functionality.

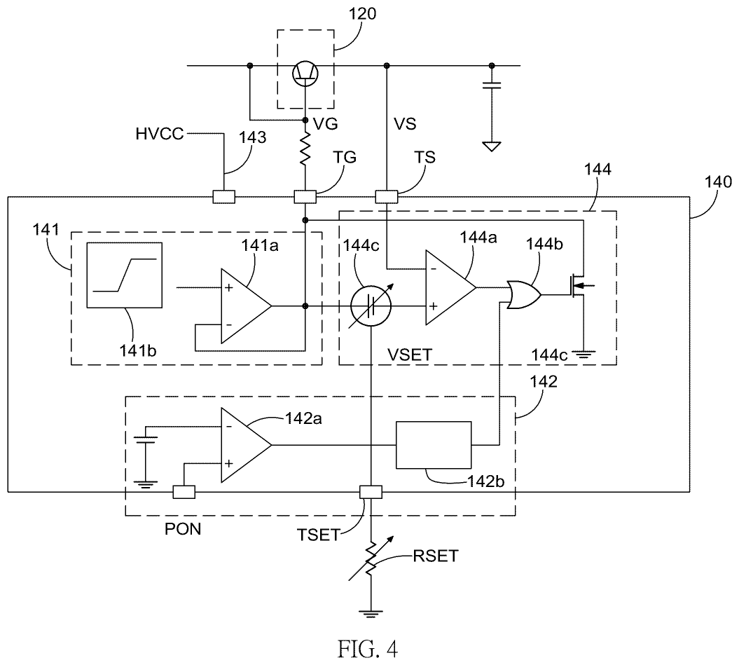

Please refer to FIG. 4, which is a schematic diagram of the voltage detection circuit according to another embodiment of the present application. Unlike the embodiment in FIG. 3, the switch circuit 120 in this embodiment utilizes a Bipolar Junction Transistor (BJT), specifically an N-type BJT. The internal circuitry and operation are the same as those in FIG. 3, which are not elaborated further here.

Through the voltage detection system and voltage detection circuit of this case, upon system start or activation, it may immediately detect whether the voltage at both terminals of the switch circuit exceeds the set threshold voltage, and if exceeded, the switch circuit is disconnected to perform short-circuit protection. This allows for immediate protection of circuit components, preventing occurrences of burning or failure.

Therefore, the present application indeed possesses novelty, progressiveness, and industrial applicability, undoubtedly meeting the requirements for a patent application under the national patent law. Accordingly, a patent application has been legally filed, earnestly praying for the patent application grant to be issued soon.

However, the above description is merely an embodiment of the present application and is not intended to limit the scope of the present application. Therefore, all equivalent modifications and variations according to the structure, and the features described in the scope of the patent application should be included within the scope of this patent application.

What is claimed is:

1. A voltage detection circuit, comprising:
a control terminal, comprising a control terminal voltage;
a load terminal, comprising a load terminal voltage; and
a voltage detection unit, coupled to the control terminal and the load terminal, converting the control terminal voltage to a low level voltage according to a voltage between the control terminal voltage and the load terminal voltage.

2. The voltage detection circuit of claim 1, wherein a detection voltage is between the control terminal voltage and the load terminal voltage, the voltage detection unit sets a threshold voltage, and when the detection voltage exceeds the threshold voltage, the voltage detection unit converts the control terminal voltage to the low level voltage.

3. The voltage detection circuit of claim 2, wherein when the detection voltage exceeds a multiple of the threshold voltage, the voltage detection unit converts the control terminal voltage to the low level voltage.

4. The voltage detection circuit of claim 3, wherein the multiple of the threshold voltage is from 1.1 to 1.5 times the threshold voltage.

5. The voltage detection circuit of claim 2, further comprising a setting terminal, wherein the setting terminal is coupled to the voltage detection unit and sets the threshold voltage through a variable resistor.

6. The voltage detection circuit of claim 1, wherein the voltage detection unit comprises a comparator, the comparator is coupled to the control terminal and the load terminal, and the comparator compares the control terminal voltage with the load terminal voltage and outputs a comparison result.

7. The voltage detection circuit of claim 6, wherein the voltage detection unit comprises a logic circuit, the logic circuit is coupled to the comparator and outputs a control signal according to the comparison result, and the voltage detection unit converts the control terminal voltage to the low level voltage according to the control signal.

8. The voltage detection circuit of claim 1, further comprising a voltage drive unit, wherein the voltage drive unit is coupled to the control terminal, generates and outputs the control terminal voltage to the control terminal to change the control terminal voltage.

9. The voltage detection circuit of claim 1, further comprising a power startup unit, wherein the power startup unit is coupled to the voltage detection unit, and outputs a start signal to the voltage detection unit.

10. A voltage detection system comprising:
a switch circuit, comprising a first terminal, a second terminal, and a control terminal, wherein the first terminal is coupled to a power source, and the second terminal is coupled to a load; and
a voltage detection circuit, coupled to the switch circuit, wherein the voltage detection circuit disconnects the switch circuit according to a voltage between the second terminal and the control terminal.

11. The voltage detection system of claim 10, wherein the voltage detection circuit disconnects the switch circuit when the voltage between the second terminal and the control terminal exceeds a multiple of a threshold voltage.

12. The voltage detection system of claim 11, wherein the multiple of the threshold voltage is from 1.1 to 1.5 times the threshold voltage.
